(19) United States
(12) Patent Application Publication
(10) Pub. No.: US 2012/0039486 A1
(43) Pub. Date: Feb. 16, 2012

(54) WIRELESS SOUND AMPLIFICATION SYSTEM WITH MICROPHONE BASED VOLUME CONTROL

(76) Inventor: Sue CHENG, Chiayi County (TW)

(21) Appl. No.: 12/853,507

(22) Filed: Aug. 10, 2010

(51) Int. Cl. H03G 3/00

(52) U.S. Cl. 381/104

(57) ABSTRACT

A wireless sound amplification system with microphone based volume control includes a wireless microphone and an audio system. The wireless microphone includes an audio pickup unit for converting sound to an audio signal, an adjustment unit configured to receive an adjustment user input, and a processing unit. The processing unit includes an amplifier configured to use a first amplification gain to amplify the audio signal from the audio pickup unit and to thereby generate an amplified audio signal. The processor further includes a controller unit configured to output a control signal based on the adjustment user input received by the adjustment unit. The processor further includes an encoder that generates a transmission signal by encoding the amplified audio signal from the amplifier and the control signal from the controller unit. The wireless microphone also includes a transmitting unit.

### BACKGROUND OF THE INVENTION

1. Field of the Invention

The invention relates to a wireless sound amplification system, and more particularly to a wireless sound amplification system with microphone based volume control.

2. Description of the Related Art

A conventional wireless sound amplification system includes a wireless microphone having a first amplification gain, an audio system, and a volume controller for the audio system that has a second amplification gain. While using the conventional wireless sound amplification system, such as during a speech or presentation, it may be inconvenient for the user to reach or access the volume controller to adjust the second amplification gain. The user may need to interrupt use of the wireless microphone and to obtain the assistance of another person to adjust the second amplification gain. Coordination of adjustment of the first and second amplification gains may then require multiple attempts to find satisfactory settings. Use of the conventional wireless sound amplification system may therefore by inconvenient, troublesome, and time consuming.

### SUMMARY OF THE INVENTION

An object of the present invention is to provide a wireless sound amplification system that has a wireless microphone for adjusting a second amplification gain of an audio system.

Another object of the present invention is to provide a volume control method for wirelessly adjusting the amplification gain of the audio system.

In an aspect, a wireless sound amplification system includes a wireless microphone. The wireless microphone includes an audio pickup unit for converting sound to an audio signal, an adjustment unit configured to receive an adjustment user input, and a first processing unit. The first processing unit includes a first amplifier configured to use a first amplification gain to amplify the audio signal from the audio pickup unit and to thereby generate an amplified audio signal. The first processor further includes a first controller unit configured to output a control signal based on the adjustment user input received by the adjustment unit. The first processor further includes an encoder that generates a transmission signal by encoding the amplified audio signal from the first amplifier and the control signal from the first controller unit. The wireless microphone also includes a transmitting unit for wirelessly outputting the transmission signal.

The audio system includes a receiving unit for receiving the transmission signal output by the transmitting unit, and a second processing unit. The second processing unit includes a decoder unit for decoding the transmission signal to recover the control signal and the amplified audio signal, and a second amplifier for receiving and amplifying the amplified audio signal using a second amplification gain. The second processing unit further includes a second controller unit for receiving the control signal and controlling the second amplification gain of the second amplifier according to the control signal.

In another aspect, a sound volume control method for a wireless sound amplification system that comprises a wireless microphone that includes an audio pickup unit, an adjustment unit, a first amplifier, a first controller unit, an encoder, and a transmitting unit, and an audio system that includes a second amplifier, a receiving unit, and a speaker, includes converting sound to an audio signal using the audio pickup unit of the wireless microphone. The method further includes amplifying the audio signal with a first amplification gain, using a first amplifier of the wireless microphone, to generate an amplified audio signal. The method also includes outputting a control signal from the first controller unit based on an adjustment user input received by the adjustment unit of the wireless microphone.

The method further includes generating a transmission signal by encoding the amplified audio signal and the control signal, and wirelessly communicating the transmission signal from the wireless microphone to the audio system. The method also includes decoding the transmission signal to recover the control signal and the amplified audio signal, and controlling a second amplification gain of the audio system according to the control signal. In addition, the method includes amplifying the amplified audio signal by the second amplification gain using a second amplifier of the audio system.

An advantage of the wireless sound amplification system with microphone based volume control is that a user may use the adjustment unit of the wireless microphone to generate a control signal that is wirelessly transmitted to the audio system to adjust the second amplification gain of the second amplifier of the audio system.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of the preferred embodiment of a wireless sound amplification system according to the present invention;

FIG. 2 is a schematic block diagram of the wireless microphone and audio system of the preferred embodiment;

FIGS. 3A and 3B are fragmentary views of the preferred embodiment in a microphone volume control mode and an audio system volume control mode; and

FIGS. 4A and 4B are a flowchart illustrating operation of the preferred embodiment.

### DETAILED DESCRIPTION OF THE PREFERRED EMBODIMENT

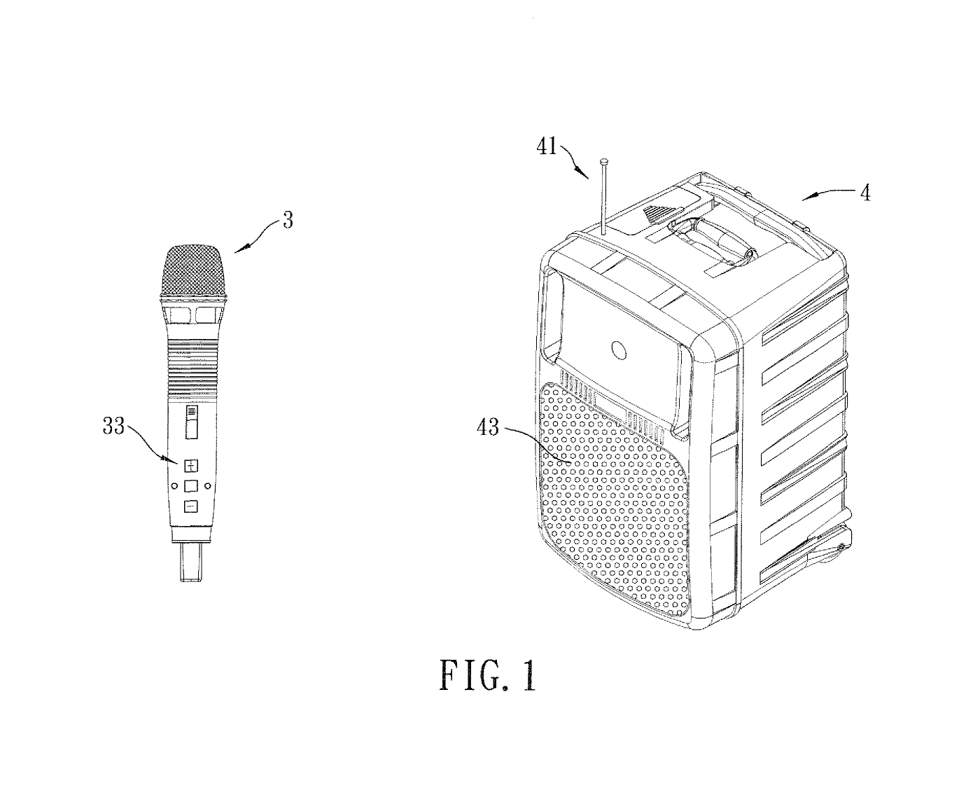

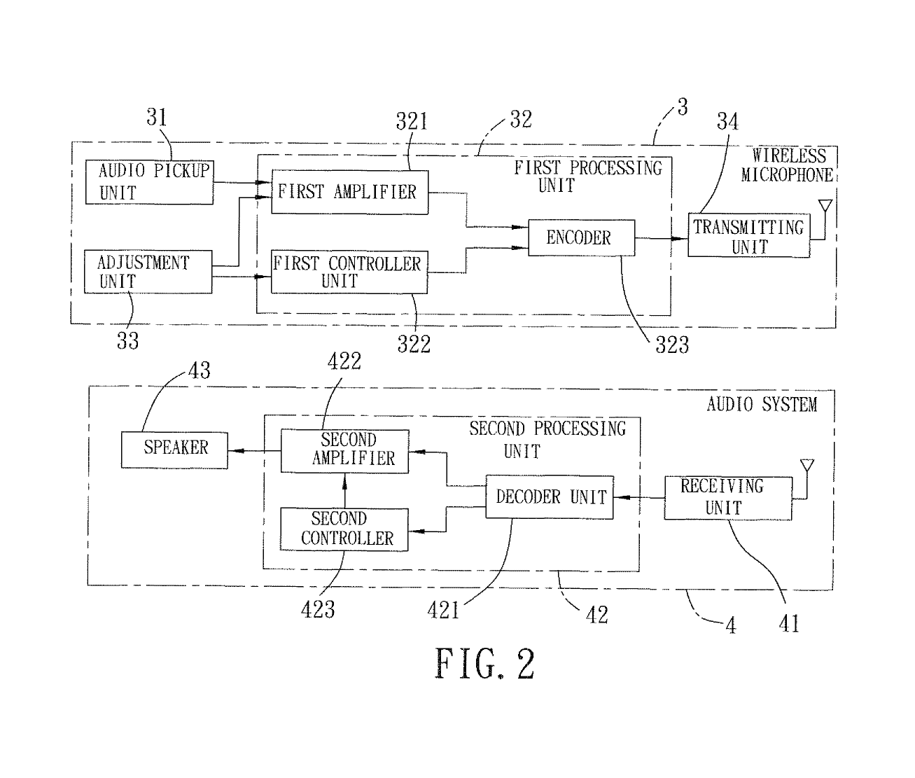

Referring to FIGS. 1 and 2, the preferred embodiment of a wireless sound amplification system according to the present invention is shown to include a wireless microphone 3 and an audio system 4.

The wireless microphone 3 includes an audio pickup unit 31, a first processing unit 32 for processing the audio signal, an adjustment unit 33 configured to receive an adjustment user input and a mode user input, and a transmitting unit 34 for wireless communication of a transmission signal. The audio pickup unit 31 picks up sound waves and converts them into an audio signal for subsequent output to the first processing unit 32.

The first processing unit 32 includes a first amplifier 321, a first controller unit 322, and an encoder 323. The first amplifier 321 is configured to use a first amplification gain to amplify the audio signal from the audio pickup unit 31 and to generate an amplified audio signal. The first controller unit 322 is configured to output a control signal based on the adjustment user input and the mode user input received by the adjustment unit 33. The encoder 323 generates a transmission signal by encoding the amplified audio signal from the first amplifier 321 and the control signal from the first controller unit 322.

The audio system 4 has a receiving unit 41 for receiving the transmission signal from the transmitting unit 34, a second processing unit 42 for decoding the transmission signal, and a speaker 43 to output sound. The receiving unit 41 is adapted for receiving wireless radio signals, such as the transmission signal, from the wireless microphone 3. Given that the receiving unit 41 is not the focus of this invention, it is not further discussed. The second processing unit 42 includes a decoder unit 421 for decoding the transmission signal to recover the control signal and the amplified audio signal, a second amplifier 422 for receiving and amplifying the amplified audio signal using a second amplification gain, and a second controller 423 for receiving the control signal and controlling the second amplification gain of the second amplifier 422 according to the control signal.

Referring to FIGS. 2, 3A, and 32, the adjustment unit 33 includes a function part 331 to provide a mode user input to the adjustment unit 33 and to switch the operational mode of the adjustment unit 33 between a microphone volume control mode and an audio system volume control mode. The function part 331 may include one or more knobs or keys. The adjustment unit 33 further includes a pair of display members 332 for displaying the selection result of the function part 331 and the operational mode of the adjustment unit 33. In this embodiment, the display members 332 are a pair of light emitting diodes that respectively represent the operational modes. The display members 332 may be disposed on opposite sides of the function part 331.

The adjustment unit 33 further includes a pair of operable parts 333 for providing the adjustment user input. The adjustment user input is received by the adjustment unit 33 and used to vary the first or second amplification gain in accordance with the operational mode of the adjustment unit 33. The operable parts 333 are formed as keys, and represent incrementing the gain (using the key marked ‘+’) and decrementing the gain (using the key marked ‘−’). In variations of the preferred embodiment, the operable parts 333 may be formed as knobs disposed on opposite sides of the function key 331.

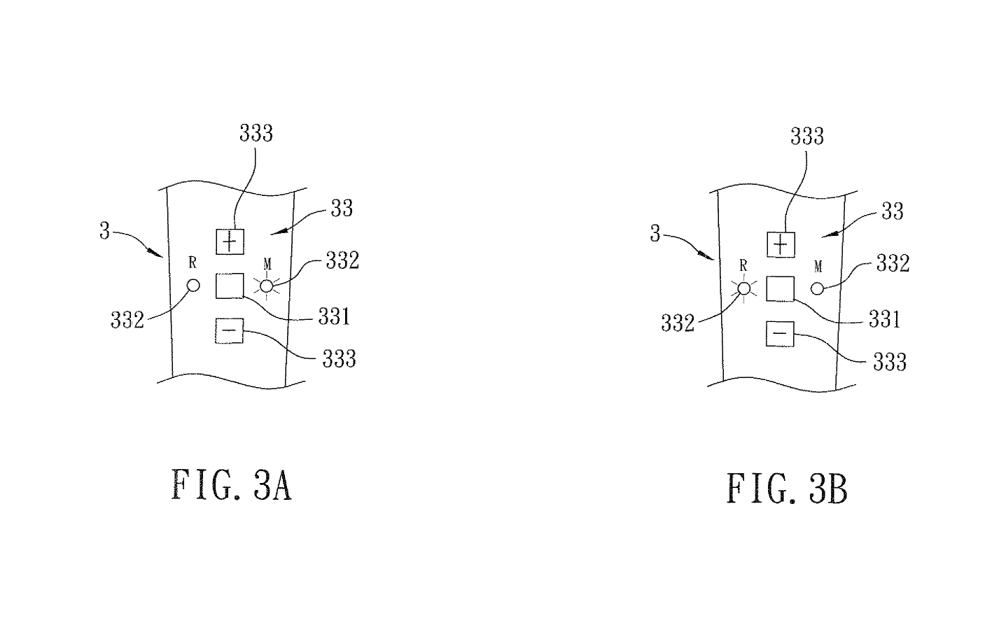

As shown in FIGS. 3A and 3B, when the function part 331 is pressed, one of the pair of display members brightens to indicate whether the operable parts 333 are operable to control either the first or the second amplification gain. In this embodiment, the display member 332 marked “M” for microphone is brightened to indicate that the first amplification gain of the first amplifier 321 may be adjusted using the pair of operable parts 333. The other display member 332 is marked “R” for receiving amplifier of the audio system 4, and is brightened to indicate that the second amplification gain of the second amplifier 422 may be adjusted using the pair of operable parts 333. In this embodiment, a pair of display members 332 are used for illustration, but in variations of the preferred embodiment, one display member 332 may be used to indicate the adjusting status of the adjustment unit 33. For example, one display member 332 may be con figured to output different flashing patterns that correspond to different operational modes of the adjustment unit 33.

Referring to FIGS. 2, 3A, and 3B, after the operational mode has been selected, the operable parts 333 can be used to increment or decrement the amplification gain that corresponds to the selected operational mode. In other words, the user can control either the first amplification gain of the first amplifier 321 or the second amplification gain of the second amplifier 422 through operation of the operable parts 333 in accordance with the selected operational mode.

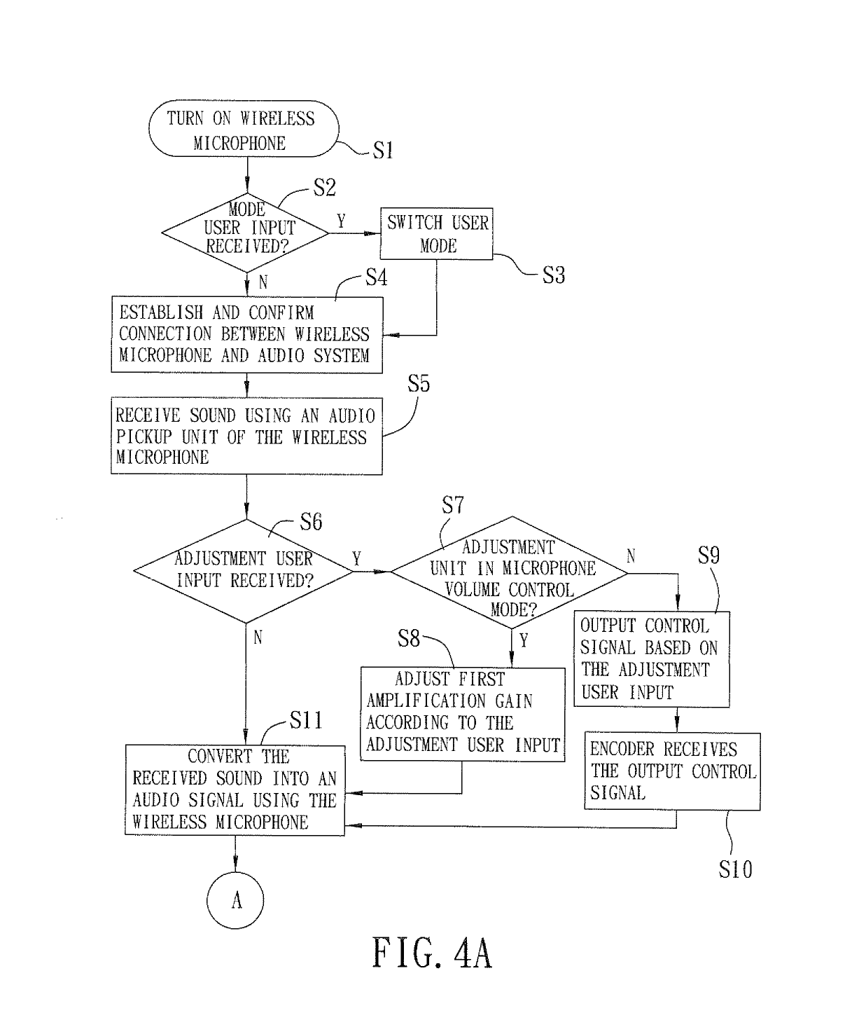

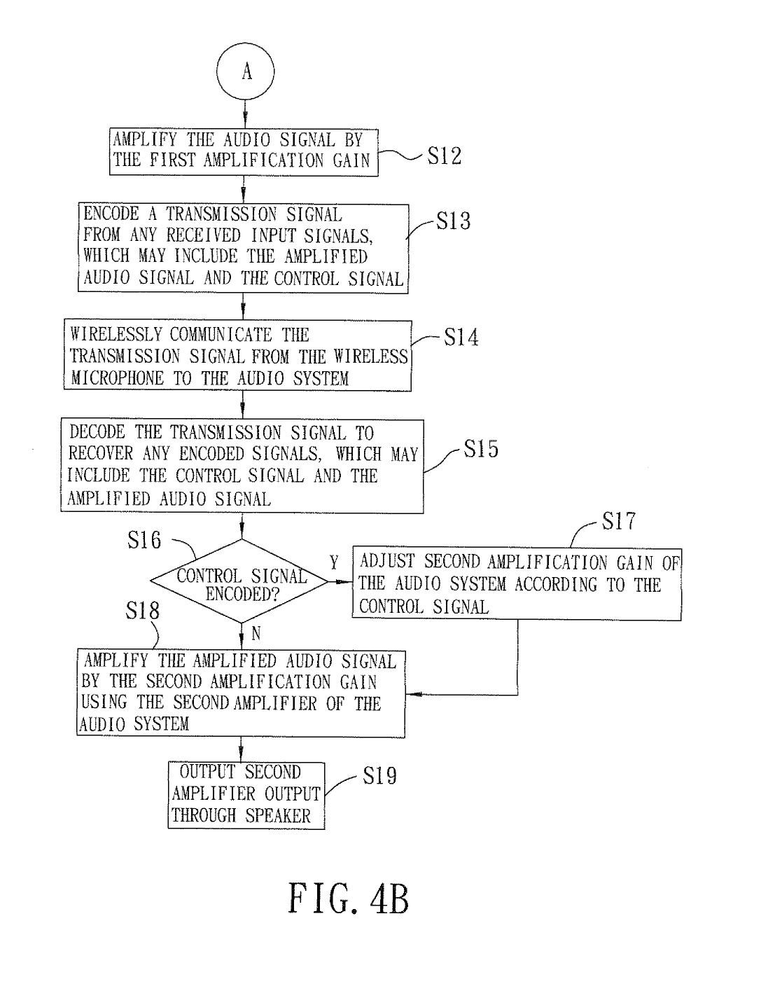

FIGS. 4A and 4B illustrate operation of the foregoing components of the preferred embodiment of the wireless sound amplification system. In operation S1, the power source of the wireless microphone 3 is turned on. After operation S1, in operation S2, the wireless sound amplification system determines whether the mode user input has been received through the function part 331 of the adjustment unit 33.

In order for a user to select one of the operational modes of the adjustment unit 33, the function part 331 may be depressed to provide the mode user input and to select either the microphone volume control mode or the audio system volume control mode. When the microphone volume control mode is selected using the function part 331, the display marked “M” is brightened (as shown in FIG. 3A), and operation of the operable parts 333 increments or decrements the first amplification gain of the first amplifier 321 to amplify the audio signal to gene rate the amplified audio signal. When the audio system volume control is selected using the function part 331, the display marked “R” is brightened (as shown in FIG. 32), and operation of the operable parts 333 causes the first controller unit 322 to generate a control signal that includes or corresponds to the second amplification gain.

If the mode user input was not received, operation of the wireless sound amplification system proceeds to operation S4. If the mode user input was received, operation S1 is followed by operation S3. In operation S3, the adjustment unit 33 is switched from one of the microphone volume control mode and the audio system volume control mode to the other one of one of the microphone volume control mode and the audio system volume control mode. Operation S3 is followed by operation S4.

In operation S4, a connection is established and confirmed between the wireless microphone 3 and the audio system 4 using wireless radio signals. In operation S5, the wireless microphone 3 receives sound using the audio pickup unit 31.

In operation S6, the wireless sound amplification system determines whether the adjustment user input has been received through the operable part 333 of the adjustment unit 33. If the adjustment user input was not received, operation of the wireless sound amplification system proceeds to operation S11. If the adjustment user input was received, operation S6 is followed by operation S7. In operation S7, the adjustment unit 33 is determined to be in either the microphone volume control mode or the audio system volume control mode.

If the adjustment unit 33 is in the microphone volume control mode, operation S7 is followed by operation S8, in which the first amplification gain is adjusted according to the adjustment user input. After operation S8, operation of the wireless sound amplification system proceeds to operation S11. If the adjustment unit 33 is in the audio system volume control mode instead of the microphone volume control mode, operation S7 is followed by operation S9. In operation S9, the first controller unit 322 outputs the control signal based on the adjustment user input received by the adjustment unit 33 of the wireless microphone 3. After operation S9, in operation S10, the output control signal is received by the encoder 323 of the wireless microphone 3. Operation S10 is followed by operation S11.

In operation S11, the audio pickup unit 31 of the wireless microphone 3 converts the received sound into the audio signal. After operation S11, in operation S12, the audio signal is amplified by the first amplification gain. Operation S12 is performed using the first amplifier 321 of the wireless microphone 3 to generate the amplified audio signal. After operation S12, in operation S13, the encoder 323 of the wireless microphone 3 is used to encode the transmission signal from any received input signals, which may include the amplified audio signal and the control signal. In operation S14, the transmission signal is wirelessly communicated from the transmitting unit 34 of the wireless microphone 3 to the receiving unit 41 of the audio system 4.

In operation S15, the transmission signal is decoded using the decoder unit 421 of the audio system 4 to recover any encoded signals, which may include the control signal and the amplified audio signal. In operation S16, whether the control signal was encoded in the transmission signal is determined. If the control signal is recovered, then operation S16 is followed by operation S17. Otherwise, operation S16 is followed by operation S18. In operation S17, the second amplification gain of the audio system 4 is adjusted according to the control signal. Operation S17 is followed by operation S18. In operation S18, the amplified audio signal is amplified by the second amplification gain using the second amplifier 422 of the audio system 4. In operation S19, the output of the second amplifier 422 is output through the speaker 43.

In summary, in accordance with the preferred embodiment of this invention, the user may conveniently adjust the output sound volume of the wireless sound amplifying system by using the adjustment unit 33 to select control of the gain of either the first amplifier 321 of the wireless microphone 3 or the second amplifier 422 of the audio system 4.

While the present invention has been described in connection with what is considered the most practical and preferred embodiments, it is understood that this invention is not limited to the disclosed embodiments but is intended to cover various arrangements included within the spirit and scope of the broadest interpretation to encompass all such modifications and equivalent arrangements.

What is claimed is:

1. A wireless sound amplification system, comprising:
a wireless microphone comprising
an audio pickup unit for converting sound to an audio signal,
an adjustment unit configured to receive an adjustment user input,
a first processing unit comprising
a first amplifier configured to use a first amplification gain to amplify the audio signal from said audio pickup unit and to thereby generate an amplified audio signal,
a first controller unit configured to output a control signal based on the adjustment user input received by said adjustment unit, and
an encoder that generates a transmission signal by encoding the amplified audio signal from said first amplifier and the control signal from said first controller unit, and
a transmitting unit for wirelessly outputting the transmission signal; and
an audio system comprising
a receiving unit for receiving the transmission signal output by said transmitting unit, and
a second processing unit comprising
a decoder unit for decoding the transmission signal to recover the control signal and the amplified audio signal,
a second amplifier for receiving and amplifying the amplified audio signal using a second amplification gain, and
a second controller unit for receiving the control signal and controlling the second amplification gain of said second amplifier according to the control signal.

2. The wireless sound amplification system as claimed in claim 1, wherein based on a mode user input received by said adjustment unit, said adjustment unit is configured to be in either a microphone volume control mode to control the first amplification gain of said first amplifier or an audio system volume control mode to control the second amplification gain of said second amplifier, the first amplification gain used by said first amplifier being set according to the adjustment user input received by said adjustment unit when said adjustment unit is in the microphone volume control mode, said first controller unit outputting the control signal based on the adjustment user input received by said adjustment unit when said adjustment unit is in the audio system volume control mode.

3. The wireless sound amplification system as claimed in claim 2, wherein said adjustment unit comprises a function part to provide the mode user input to the adjustment unit and to switch the operational mode of said adjustment unit between the microphone volume control mode and the audio system volume control mode, a display unit for displaying the operational mode of said adjustment unit, and an operable part for providing the adjustment user input received by said adjustment unit to thereby vary the first or second amplification gain in accordance with the operational mode of said adjustment unit.

4. The wireless sound amplification system as claimed in claim 3, wherein each of said function part and said operable part comprises one or more keys, and said display unit comprises a light.

5. The wireless sound amplification system as claimed in claim 3, wherein each of said function part and said operable part comprises one or more knobs, and said display unit comprises a light.

6. A wireless microphone configured for wireless communication with an audio system, said wireless microphone comprising:
an audio pickup unit for converting sound to an audio signal;
an adjustment unit configured to receive an adjustment user input for controlling a volume of the audio system;
a processing unit comprising
an amplifier configured to use a first amplification gain to amplify the audio signal from said audio pickup unit and to thereby generate an amplified audio signal,
a controller unit configured to output a control signal based on the adjustment user input received by said adjustment unit for controlling amplification by the audio system, and
an encoder that generates a transmission signal by encoding the amplified audio signal from said amplifier and the control signal from said controller unit; and
a transmitting unit for wirelessly outputting the transmission signal to the audio system for amplification of the amplified audio signal using a second amplification gain which is controlled by the audio system according to the control signal.

7. The wireless microphone as claimed in claim 6, wherein based on a mode user input received by said adjustment unit, said adjustment unit is configured to be in either a microphone volume control mode to control the first amplification gain of said amplifier or an audio system volume control mode to control the second amplification gain of the audio system, the first amplification gain used by said amplifier being set according to the adjustment user input received by said adjustment unit when said adjustment unit is in the microphone volume control mode, said controller unit outputting the control signal based on the adjustment user input received by said adjustment unit when said adjustment unit is in the audio system volume control mode.

8. The wireless microphone as claimed in claim 7, wherein said adjustment unit comprises a function part to provide the mode user input to the adjustment unit and to switch the operational mode of said adjustment unit between the microphone volume control mode and the audio system volume control mode, a display unit for displaying the operational mode of said adjustment unit, and an operable part for providing the adjustment user input received by said adjustment unit to thereby vary the first or second amplification gain in accordance with the operational mode of said adjustment unit.

9. The wireless microphone as claimed in claim 8, wherein each of said function part and said operable part comprises one or more keys.

10. The wireless microphone as claimed in claim 8, wherein each of said function part and said operable part comprises one or more knobs.

11. The wireless microphone as claimed in claim 8, wherein said display unit comprises a light.

12. A volume control method of a wireless sound amplification system that comprises a wireless microphone comprising an audio pickup unit, an adjustment unit, a first amplifier, a first controller unit, an encoder, and a transmitting unit, and an audio system comprising a second amplifier, a receiving unit, and a speaker, the volume control method comprising:
(a) converting sound to an audio signal using the audio pickup unit of the wireless microphone;
(b) amplifying the audio signal with a first amplification gain, using a first amplifier of the wireless microphone, to generate an amplified audio signal;
(b) outputting a control signal from the first controller unit based on an adjustment user input received by the adjustment unit of the wireless microphone;
(c) generating a transmission signal by encoding the amplified audio signal and the control signal;
(d) wirelessly communicating the transmission signal from the wireless microphone to the audio system;
(e) decoding the transmission signal to recover the control signal and the amplified audio signal;
(f) controlling a second amplification gain of the audio system according to the control signal; and
(g) amplifying the amplified audio signal by the second amplification gain using a second amplifier of the audio system.

13. The volume control method of claim 12, wherein the adjustment unit is configurable to be in a microphone volume control mode to control the first amplification gain of the first amplifier, or an audio system volume control mode to control the second amplification gain of the second amplifier.
